(19) United States
(12) Patent Application Publication
(10) Pub. No.: US 2009/0162561 A1
(43) Pub. Date: Jun. 25, 2009

(54) METHODS FOR MAKING BARRIER COATINGS COMPRISING TAGGANTS AND COMPONENTS HAVING THE SAME

(76) Inventors: GLEN HAROLD KIRBY, Liberty Township, OH (US); Stephen Mark Whiteker, Covington, KY (US); Brett Allan Boutwell, West Chester, OH (US); Jessica Lee Licardi, Mason, OH (US)

Correspondence Address: GENERAL ELECTRIC COMPANY, GE AVIATION, ONE NEUMANN WAY MD H17, CINCINNATI, OH, 45215, US

(21) Appl. No.: 11/959,751

(22) Filed: Dec. 19, 2007

(51) Int. Cl. C23C 4/04; B05D 1/00; C23C 16/00; C09D 1/00; C09K 11/77; C09K 11/81; C09K 11/80; C09K 11/78

(52) U.S. Cl. 427/452; 428/457; 427/585; 106/286.1; 106/286.2; 252/301.4 R

(57) ABSTRACT

Methods for making barrier coatings including a taggant involving providing a barrier coating, and adding from about 0.01 mol % to about 30 mol % of a taggant to the barrier coating wherein the taggant comprises a rare earth element selected from lanthanum, cerium, praseodymium, neodymium, promethium, samarium, europium, gadolinium, terbium, dysprosium, holmium, erbium, ytterbium, and lutetium, salts thereof, silicates thereof, oxides thereof, zirconates thereof, hafnates thereof, titanates thereof, tantalates thereof, cerates thereof, aluminates thereof, aluminosilicates thereof, phophates thereof, niobates thereof, borates thereof, and combinations thereof.

### STATEMENT OF GOVERNMENT RIGHTS

This invention was made, at least in part, with a grant from the Government of the United States (Contract No. N00019-04-C-0093, from the Department of the Navy). The Government may have certain rights to the invention.

### TECHNICAL FIELD

Embodiments described herein generally relate to methods for making barrier coatings comprising taggants and components having the same. More particularly, embodiments herein generally describe methods for making barrier coatings including a taggant comprising providing a barrier coating, and adding from about 0.01 mol % to about 30 mol % of a taggant to the barrier coating wherein the taggant comprises a rare earth element.

### BACKGROUND OF THE INVENTION

Higher operating temperatures for gas turbine engines are continuously being sought in order to improve their efficiency. However, as operating temperatures increase, the high temperature durability of the components of the engine must correspondingly increase. Significant advances in high temperature capabilities have been achieved through the formulation of iron, nickel, and cobalt-based superalloys. While superalloys have found wide use for components used throughout gas turbine engines, and especially in the higher temperature sections, alternative lighter-weight substrate materials have been proposed.

Ceramic matrix composites (CMCs) are a class of materials that consist of a reinforcing material surrounded by a ceramic matrix phase. Such materials, along with certain monolithic ceramics (i.e. ceramic materials without a reinforcing material), are currently being used for higher temperature applications. Some examples of common CMC matrix materials can include silicon carbide, silicon nitride, alumina, silica, mullite, alumina-silica, alumina-mullite, and alumina-silica-boron oxide. Some examples of common CMC reinforcing materials can include, but should not be limited to, silicon carbide, silicon nitride, alumina, silica, mullite, alumina-silica, alumina-mullite, and alumina-silica-boron oxide. Some examples of monolithic ceramics may include silicon carbide, silicon nitride, silicon aluminum oxynitride (SiAlON), and alumina. Using these ceramic materials can decrease the weight, yet maintain the strength and durability, of turbine components. Therefore, such materials are currently being considered for many gas turbine components used in higher temperature sections of gas turbine engines, such as airfoils (e.g. compressors, turbines, and vanes), combustors, shrouds and other like components that would benefit from the lighter-weight these materials can offer.

CMC and monolithic ceramic components can be coated with environmental barrier coatings (EBCs) and/or thermal barrier coatings (TBCs) to protect them from the harsh environment of high temperature engine sections. EBCs can provide a dense, hermetic seal against the corrosive gases in the hot combustion environment while TBCs can set up a thermal gradient between the coating surface and the backside of the component, which is actively cooled. In this way, the surface temperature of the component can be reduced below the surface temperature of the TBC. In some instances, a TBC may also be deposited on top of an EBC in order to reduce the surface temperature of the EBC to below the surface temperature of the TBC. This approach lowers the operating temperature at which the EBC must perform.

Currently, most EBCs used for CMC and monolithic ceramic components consist of a three-layer coating system including a silicon bond coat layer, at least one transition layer comprising mullite, barium strontium aluminosilicate (BSAS), combinations of mullite and BSAS, a rare earth disilicate, or a combination thereof, and an outer layer comprising BSAS, a rare earth monosilicate, or a combination thereof. The rare earth elements in the mono- and disilicate coating layers may comprise yttrium, leutecium, ytterbium, or some combination thereof. Together, these layers can provide environmental protection for the CMC or monolithic ceramic component.

TBCs used for CMC and monolithic ceramic components generally consist of refractory oxide materials that are deposited with special microstructures to mitigate thermal or mechanical stresses due to thermal expansion mismatch or contact with other components in the engine environment. These microstructures may include dense coating layers with vertical cracks or grains, porous microstructures, and combinations thereof. The refractory oxide material typically comprises yttria-doped zirconia, yttria-doped hafnia, but may also include zirconia or hafnia doped with calcia, baria, magnesia, strontia, ceria, ytterbia, leuticia, and any combination of the same. Other examples of acceptable refractory oxides for use as a TBC can include, but should not be limited to, yttrium disilicate, ytterbium disilicate, lutetium disilicate, yttrium monosilicate, ytterbium monosilicate, lutetium monosilicate, zircon, hafnon, BSAS, mullite, magnesium aluminate spinel, and rare earth aluminates.

Unfortunately, virtually all of these materials, both the EBCs and the TBCs, are white or semi-transparent in color depending on the porosity of the coating system. As a result, it can be difficult to determine the chemistry or integrity of the individual layers by visual inspection alone. More specifically, since such coating thicknesses are typically built up in a layer-by-layer fashion, it can be challenging to determine which layer should be deposited next, especially when there are time gaps between the deposition of successive layers. Moreover, with each layer being the same or similar in color, using visual inspection to determine whether a breach exists in a particular layer can be nearly impossible.

Accordingly, there remains a need for methods for making barrier coatings that allow for the determination of the chemistry and integrity of the individual layers EBC/TBC layers by visual inspection, as well as methods for making components comprising such barrier coatings.

### BRIEF DESCRIPTION OF THE INVENTION

Embodiments herein generally relate to methods for making barrier coatings including a taggant comprising providing a barrier coating, and adding from about 0.01 mol % to about 30 mol % of a taggant to the barrier coating wherein the taggant comprises a rare earth element selected from the group consisting of lanthanum, cerium, praseodymium, neodymium, promethium, samarium, europium, gadolinium, terbium, dysprosium, holmium, erbium, ytterbium, and lutetium, salts thereof, silicates thereof, oxides thereof, zirconates thereof, hafnates thereof, titanates thereof, tantalates thereof, cerates thereof, aluminates thereof, aluminosilicates thereof, phophates thereof, niobates thereof, borates thereof, and combinations thereof.

Embodiments herein also generally relate to methods for making a component having a tagged barrier coating comprising providing a component, and applying a barrier coating and a from about 0.01 mol % to about 30 mol % of a taggant to the component to produce the component having the tagged barrier coating wherein the taggant comprises a rare earth element selected from the group consisting of lanthanum, cerium, praseodymium, neodymium, promethium, samarium, europium, gadolinium, terbium, dysprosium, holmium, erbium, ytterbium, and lutetium, salts thereof, silicates thereof, oxides thereof, zirconates thereof, hafnates thereof, titanates thereof, tantalates thereof, cerates thereof, aluminates thereof, aluminosilicates thereof, phophates thereof, niobates thereof, borates thereof, and combinations thereof.

These and other features, aspects and advantages will become evident to those skilled in the art from the following disclosure.

### BRIEF DESCRIPTION OF THE DRAWINGS

While the specification concludes with claims particularly pointing out and distinctly claiming the invention, it is believed that the embodiments set forth herein will be better understood from the following description in conjunction with the accompanying figures, in which like reference numerals identify like elements.

FIG. 1 is a schematic cross sectional view of one embodiment of a ceramic component comprising a tagged environmental barrier coating having a tagged transition layer in accordance with the description herein; and

FIG. 2. is a schematic cross sectional view of one embodiment of a ceramic component comprising a tagged thermal barrier coating having a tagged bond coat layer and a tagged refractory layer in accordance with the description herein.

### DETAILED DESCRIPTION OF THE INVENTION

Embodiments described herein generally relate to methods for making barrier coatings comprising taggants suitable for use on ceramic matrix composites (CMCs) or monolithic ceramics. More specifically, embodiments described herein generally describe methods for making barrier coatings including a taggant comprising providing a barrier coating, and adding from about 0.01 mol % to about 30 mol % of a taggant to the barrier coating wherein the taggant comprises a rare earth element.

The barrier coatings described herein may be suitable for use in conjunction with components comprising CMCs or monolithic ceramics. As used herein, “CMCs” refers to both silicon-containing matrix and reinforcing materials and oxide-oxide matrix and reinforcing materials. Some examples of CMCs acceptable for use herein can include, but should not be limited to, materials having a matrix and reinforcing fibers comprising silicon carbide, silicon nitride, alumina, silica, mullite, alumina-mullite, alumina-silica, alumina-silica-boron oxide, and combinations thereof. As used herein, “monolithic ceramics” refers to materials comprising silicon carbide, silicon nitride, silicon aluminum oxynitride (SiAlON), and alumina. Herein, CMCs and monolithic ceramics are collectively referred to as “ceramics.”

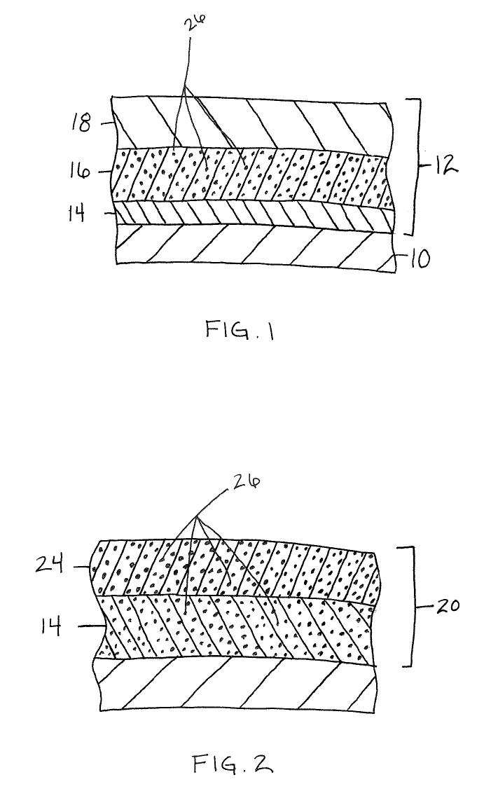

As used herein, the term “barrier coating(s)” can refer to environmental barrier coatings (EBCs), thermal barrier coatings (TBCs), and combinations thereof, and may comprise at least one barrier coating composition, as described herein below. The barrier coatings herein may be suitable for use on ceramic components 10 found in high temperature environments, such as those present in gas turbine engines, as shown generally in FIGS. 1 and 2. “Ceramic component” refers to a component made from “ceramics,” as defined herein.

More specifically, EBC 12 may generally comprise at least a three-layer coating system including a bond coat layer 14, at least one transition layer 16, and an outer layer 18, as shown generally in FIG. 1. The bond coat layer 14 may comprise any of silicon, a noble metal silicide (such as tantalum silicide, niobium silicide, molybdenum silicide, and the like), or an aluminide (such as nickel aluminide, platinum aluminide, iron aluminide, ruthenium aluminide, and the like). The at least one transition layer 16 may comprise a composition selected from the group consisting of mullite, BSAS, a rare earth disilicate, and combinations thereof, and the outer layer 18 may comprise BSAS, a rare earth monosilicate, a rare earth disilicate, and combinations thereof. Any one or more of such layers may comprise a taggant as indicated in FIG. 1 and as described herein below.

More particularly, in one embodiment, the EBC may comprise a silicon bond coat layer, a transition layer comprising a combination of mullite and BSAS, and a BSAS outer layer. In another embodiment, the EBC may include a silicon bond coat layer, a rare-earth disilicate transition layer, and a BSAS outer layer. In yet another embodiment, the EBC may include a silicon bond coat layer, a rare-earth disilicate transition layer, and a rare earth monosilicate outer layer. In still another embodiment, the EBC may include a silicon bond coat layer, a plurality of transition layers including at least a first transition layer comprising a rare-earth disilicate, a second transition layer comprising BSAS, and a third transition layer comprising a rare earth disilicate, as well as a rare earth monosilicate outer layer. In another embodiment, the EBC may include a silicon bond coat layer, a rare earth disilicate transition layer, a BSAS transition layer, and a rare earth disilicate or monosilicate outer layer. The rare earth elements in the mono- and disilicate coating layers may comprise yttrium, leutecium, ytterbium, and combinations thereof.

TBC 20 may generally comprise at least a refractory layer 22, and in one embodiment, a refractory layer 22 and a bond coat layer 24, as shown generally in FIG. 2. The refractory layer 22 can include a material having a microstructure that can be dense and vertically cracked, porous, or porous and vertically cracked. Moreover, refractory layer 22 of TBC 20 may comprise any of yttria-doped zirconia, yttria-doped hafnia, zirconia or hafnia doped with calcia, baria, magnesia, strontia, ceria, ytterbia, leuticia, and combinations thereof. Other refractory layer 22 materials that may be suitable for use in TBC 20 may include, but should not be limited to, yttrium disilicate, ytterbium disilicate, lutetium disilicate, yttrium monosilicate, ytterbium monosilicate, lutetium monosilicate, zircon, hafnon, BSAS, mullite, magnesium aluminate spinel, rare earth aluminates, and combinations thereof.

As previously mentioned, similar to the EBC, TBC 20 may also comprise a bond coat 14 layer upon which the refractory layer 22 can be deposited. The bond coat layer 14 can be applied to ceramic component 10 using conventional techniques and may comprise any of silicon, a noble metal silicide (such as tantalum silicide, niobium silicide, molybdenum silicide, and the like), or an aluminide (such as nickel aluminide, platinum aluminide, iron aluminide, ruthenium aluminide, and the like). The TBC can also be deposited on top of an EBC. In such instances, the TBC and EBC may comprise any combination of the aforementioned layers. As explained herein below, any one or more of such layers may comprise a taggant as indicated in FIG. 2.

As previously discussed, at least one taggant 26 may be added to EBC 12, TBC 20, or individual layers thereof as desired to produce a barrier coating comprising a taggant, or a “tagged barrier coating,” as explained herein below. As used herein, “taggant” refers to any dopant capable of imparting a visible color or fluorescence to an EBC or TBC as described herein, and is in addition to similar elements that may be present in the EBC or TBC. In one embodiment, taggant 26 may comprise at least one rare earth element. As used herein, “rare earth element” refers to any rare earth including lanthanum, cerium, praseodymium, neodymium, promethium, samarium, europium, gadolinium, terbium, dysprosium, holmium, erbium, ytterbium, and lutetium, salts thereof, silicates thereof, oxides thereof, zirconates thereof, hafnates thereof, titanates thereof, tantalates thereof, cerates thereof, aluminates thereof, aluminosilicates thereof, phophates thereof, niobates thereof, borates thereof, and combinations thereof. Some examples of salts can include chlorides, nitrates, sulfates, phosphates, hydroxides, acetates, oxalates, phthalates, fluorides, and combinations thereof.

Certain rare earth elements may be of particular interest for use as a taggant 26 for their ability to tint most any white EBC/TBC a visible color. More specifically, europium can tint red, cerium can tint blue, dysprosium can tint blue, terbium can tint green, neodymium can tint green, lanthanum can tint black and erbium can tint pink.

Moreover, the taggants can be fluoresced using a radiation source providing monochromatic or polarized light, as well as radiation from other frequency bands, including the non-visible spectrum, for improved visibility. Examples of light sources acceptable for use herein may include, but should not be limited to, monochromatic lasers of targeted wavelength tuned to make the selected taggant fluoresce, black lights, UV light sources, x-ray sources, Infrared (IR) sources, microwave sources, and the like.

While the amount of taggant added to the barrier coating can vary, in general, the taggant may account for from about 0.01 mol % to about 30 mol % of the tagged barrier coating, whether added to the barrier coating as a whole, or to a particular layer thereof. As used herein “tagged” barrier coating refers to an environmental barrier coating, a thermal barrier coating, or a combination thereof, having at least one taggant added thereto. The addition of the taggant may occur either before or after the barrier coating is applied to the component, as explained herein below.

As explained herein below, the taggant may be added to the barrier coating, and the barrier coating applied to the ceramic component, in variety of ways. In one embodiment, the taggant may be doped within a ceramic powder of the desired barrier coating and the resulting tagged powder can be applied to the ceramic component to produce the tagged barrier coating. In this instance, the application of the tagged EBC or TBC may be accomplished using any conventional method known to those skilled in the art, including, but not limited to, plasma spray deposition and slurry deposition (i.e. spraying, dipping, rolling, tape application, etc).

In another embodiment, the taggant may be added to a slurry comprising the barrier coating and the resulting tagged slurry can be slurry deposited on the ceramic component using common methods known to those skilled in the art. In this instance, the rare earth taggant may comprise europium, cerium, dysprosium, terbium, neodymium, lanthanum, erbium, gadolinium, oxides thereof, salts thereof, and combinations thereof. The taggant can either react with the EBC or TBC in the slurry to produce a unitary layer, or the taggant can remain a distinct phase after the sintering process, described briefly herein below.

In another embodiment, a conventional barrier coating can be deposited on the ceramic component using common techniques known to those skilled in the art followed by infiltration of the taggant into the applied barrier coating. For example, a conventional barrier coating can be deposited on a ceramic component using slurry deposition, for example. The deposited barrier coating can then be dried and back infiltrated with a precursor solution comprising a taggant. The precursor solution may comprise an aqueous salt solution of rare earth chloride, nitrate, sulfate, phosphate, hydroxide, acetate, oxalate, phthalate, fluoride, etc, wherein the rare earth element comprises europium, cerium, dysprosium, terbium, neodymium, lanthanum, erbium, gadolinium, and combinations thereof. Alternately, the precursor solution may comprise a solution of an organic solvent and a rare earth methoxyethoxide, or rare earth isopropoxide. The taggants (i.e. rare earth elements and/or ions) deposited from the precursor solution can react with either oxygen to form an oxide, or with excess silica to form a silicate as a distinct phase within the barrier coating layers after sintering. The taggants deposited from the precursor solution will still be “taggants,” as defined herein, even after reacting with the barrier coating material after sintering.

In another embodiment, the taggant may be applied as a distinct taggant layer between any of the layers of the EBC coating, on top of the EBC coating, between the ceramic and the EBC coating, between the ceramic and an TBC coating, between a bond coat and a TBC coating, between an EBC and TBC coating, or on top of a TBC coating. In this embodiment, a rare earth oxide, RE₂O₃, or complex oxide such as rare earth silicates, aluminates, aluminosilicates, zirconates, hafnates, tantalates, cerates, niobates, titanates, borates, and phosphates, may be used as the taggant layer. The rare earth element may be europium, cerium, dysprosium, terbium, neodymium, lanthanum, erbium, gadolinium and combinations thereof. The thickness of the taggant layer may range from about 0.5 microns to about 75 microns.

In still another embodiment, the taggant may be doped into an ingot or metered into a reactor as a gaseous precursor for use with electron beam physical vapor deposition (EBPVD) or chemical vapor deposition (CVD).

Once the tagged barrier coating is applied to the ceramic component, it can be dried, and optionally sintered if needed to densify the tagged barrier coating. Those skilled in the art will understand that the tagged barrier coatings applied using slurry deposition can require sintering, while other methods, such as plasma spraying and chemical vapor deposition, may or may not. However, if used, sintering may be carried out using conventional techniques including heat treating in a refractory-lined furnace, laser sintering, microwave sintering, or other like methods. Conventional sintering temperatures can be from about 400° C. to about 1400° C. when the component comprises a silicon-containing ceramic matrix composite, and from about 400° C. to about 1100° C. when the component comprises an oxide-oxide ceramic matrix composite

A variety of ceramic components may benefit from the protection of tagged environmental and/or thermal barrier coatings, such as vanes, blades, nozzles, heat shields, combustor liners, flaps, seals, and the like. The incorporation of the taggants into the barrier coating can allow for the determination of the chemistry and/or integrity of the individual layers of the barrier coating by visual inspection, which can significantly decrease the time need to make such assessments. More specifically, since such coating thicknesses are typically built up in a layer-by-layer fashion, each layer can be tagged a different color (or fluoresce differently), thereby making it easier to determine which layer should be deposited next. Moreover, tagging each layer with a different color (or fluorescence) allows for the use of visual inspection to determine whether a breach exists in a particular layer

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A method for making a barrier coating comprising a taggant comprising:
providing a barrier coating; and
adding from about 0.01 mol % to about 30 mol % of a taggant to the barrier coating
wherein the taggant comprises a rare earth element selected from the group consisting of lanthanum, cerium, praseodymium, neodymium, promethium, samarium, europium, gadolinium, terbium, dysprosium, holmium, erbium, ytterbium, and lutetium, salts thereof, silicates thereof, oxides thereof, zirconates thereof, hafnates thereof, titanates thereof, tantalates thereof, cerates thereof, aluminates thereof, aluminosilicates thereof, phophates thereof, niobates thereof, borates thereof, and combinations thereof.

2. The method of claim 1 wherein the barrier coating comprises an environmental barrier coating, a thermal barrier coating, or a combination thereof.

3. The method of claim 2 wherein the environmental barrier coating comprises at least one of a bond coat layer, a transition layer, or an outer layer.

4. The method of claim 2 wherein the thermal barrier coating comprises a refractory layer and an optional bond coat layer.

5. The method of claim 3 wherein the environmental barrier coating bond coat layer comprises a composition selected from the group consisting of silicon, a noble metal silicide, or an aluminide, the transition layer comprises a composition selected from the group consisting of BSAS, mullite, a rare earth disilicate, and combinations thereof, and the outer layer comprises a composition selected from the group consisting of BSAS, a rare earth monosilicate, a rare earth disilicate, and combinations thereof.

6. The method of claim 4 wherein the thermal barrier coating refractory layer comprises a material selected from the group consisting of yttria-doped zirconia, yttria-doped hafnia, zirconia doped with calcia, baria, magnesia, strontia, ceria, ytterbia, leuticia, and combinations thereof, hafnia doped with calcia, baria, magnesia, strontia, ceria, ytterbia, leuticia, and combinations thereof, yttrium disilicate, ytterbium disilicate, lutetium disilicate, yttrium monosilicate, ytterbium monosilicate, lutetium monosilicate, zircon, hafnon, BSAS, mullite, magnesium aluminate spinel, rare earth aluminates, and combinations thereof.

7. The method of claim 2 wherein the taggant is capable of being fluoresced by a radiation source.

8. The method of claim 3 wherein each layer comprises a taggant and each taggant is different.

9. A method for making a component having a tagged barrier coating comprising:
providing a component; and
applying a barrier coating and a from about 0.01 mol % to about 30 mol % of a taggant to the component to produce the component having the tagged barrier coating
wherein the taggant comprises a rare earth element selected from the group consisting of lanthanum, cerium, praseodymium, neodymium, promethium, samarium, europium, gadolinium, terbium, dysprosium, holmium, erbium, ytterbium, and lutetium, salts thereof, silicates thereof, oxides thereof, zirconates thereof, hafnates thereof, titanates thereof, tantalates thereof, cerates thereof, aluminates thereof, aluminosilicates thereof, phophates thereof, niobates thereof, borates thereof, and combinations thereof.

10. The method of claim 9 wherein the component is a gas turbine engine component comprising a ceramic selected from the group consisting of silicon carbide, silicon nitride, alumina, silica, mullite, alumina-mullite, alumina-silica, alumina-silica-boron oxide, silicon aluminum oxynitride, and combinations thereof.

11. The method of claim 10 wherein the barrier coating comprises an environmental barrier coating, a thermal barrier coating, or a combination thereof.

12. The method of claim 11 wherein the environmental barrier coating comprises at least one of a bond coat layer, a transition layer, or an outer layer.

13. The method of claim 11 wherein the thermal barrier coating comprises a refractory layer and an optional bond coat layer.

14. The method of claim 12 wherein the environmental barrier coating bond coat layer comprises a composition selected from the group consisting of silicon, a noble metal silicide, or an aluminide, the transition layer comprises a composition selected from the group consisting of BSAS, mullite, a rare earth disilicate, and combinations thereof, and the outer layer comprises a composition selected from the group consisting of BSAS, a rare earth monosilicate, a rare earth disilicate, and combinations thereof.

15. The method of claim 13 wherein the thermal barrier coating refractory layer comprises a material selected from the group consisting of yttria-doped zirconia, yttria-doped hafnia, zirconia doped with calcia, baria, magnesia, strontia, ceria, ytterbia, leuticia, and combinations thereof, hafnia doped with calcia, baria, magnesia, strontia, ceria, ytterbia, leuticia, and combinations thereof, yttrium disilicate, ytterbium disilicate, lutetium disilicate, yttrium monosilicate, ytterbium monosilicate, lutetium monosilicate, zircon, hafnon, BSAS, mullite, magnesium aluminate spinel, rare earth aluminates, and combinations thereof.

16. The method of claim 10 wherein applying the barrier coating and the taggant comprises doping the taggant within a powder comprising the barrier coating to produce a tagged powder and applying the tagged powder to the ceramic component using a method selected from the group consisting of plasma spray deposition or slurry deposition.

17. The method of claim 10 wherein applying the barrier coating and the taggant comprises adding the taggant to a slurry comprising the barrier coating to produce a tagged slurry and depositing the tagged slurry on the ceramic component using slurry deposition.

18. The method of claim 10 wherein applying the barrier coating and the taggant comprises depositing the barrier coating on the ceramic component to produce an applied barrier coating followed by infiltrating the taggant into the applied barrier coating.

19. The method of claim 10 wherein applying the barrier coating and taggant comprises applying the taggant to the ceramic component as a distinct taggant layer.

20. The method of claim 10 wherein applying the barrier coating and the taggant comprises doping the taggant into an ingot and depositing the tagged barrier coating onto the ceramic component using a method selected from the group consisting of electron beam physical vapor deposition or chemical vapor deposition.
